(19) United States
(12) Patent Application Publication
(10) Pub. No.: US 2010/0001814 A1
(43) Pub. Date: Jan. 7, 2010

(54) THIN FILM ACOUSTIC REFLECTOR STACK

(75) Inventors: Hans-Peter Lobl, Monschau-Imgenbroich (DE); Arnd Ritz, Heinsberg (DE); Christof Metzmacher, Lacalamine (DE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/721,972

(22) PCT Filed: Dec. 7, 2005
(86) PCT No.: PCT/IB2005/054097

§ 371 Date: Sep. 28, 2009

(30) Foreign Application Priority Data
Dec. 15, 2004 (EP) 04106590.5

(51) Int. Cl. H03H 9/02; C23C 14/35

(52) U.S. Cl. 333/193; 204/192.15; 204/298.17

(57) ABSTRACT

The invention refers to a method for the fabrication of a thin film acoustic reflector stack with alternating layers of a first and a second material having different acoustic characteristic impedances, wherein the layers are deposited alternately by a reactive pulsed dc magnetron sputtering process. The invention further comprises an acoustic reflector stack fabricated thereby and an arrangement for performing the method.

The invention refers to a method for the fabrication of a thin film acoustic reflector stack with alternating layers of a first and a second material having different acoustic characteristic impedances, an acoustic reflector stack fabricated thereby and an arrangement for performing the method.

These reflector stacks are used with bulk acoustic wave (=BAW) filters and resonators and consist of λ/4 layers (λ=acoustical wavelength) of materials with alternating high and low acoustical impedance. Different thin film techniques for the deposition of SiO2 and Ta2O5 are known. However the requirements on materials for BAW reflectors are quite high: high temperature stability, high density, low stress level, low surface roughness. Layers prepared so far using different deposition processes do not fulfil all requirements. Especially evaporated Ta2O5 films show crystallisation at processing temperatures above 400° C. Thus a deposition process capable to deliver acoustic Bragg reflectors with good properties was needed

### SUMMARY OF THE INVENTION

The inventive method for the fabrication of a thin film acoustic reflector stack with alternating layers of a first and a second material having different acoustic characteristic impedances, wherein at least one of the layers is deposited by a reactive dc magnetron sputtering process fulfill the above requirements, especially lack of crystallization at temperatures above 400° C. necessary for further processing and low mechanical stress (low wafer bow).

In order to stabilize the process further the sputtering process can be pulsed. Although the invention comprises building of the other layer by a different process, in a preferred embodiment both layers are deposited alternately by the sputtering process.

An advantageous embodiment of the inventive method, wherein a plurality of substrates are placed in a vacuum reaction chamber containing an inert gas and a reaction gas, comprises the steps of:
a) moving the substrates through a deposition zone for the first material, having a magnetron sputter source with a precursor of the first material, collecting a thin layer of the first material,
b) moving the substrates through a reaction zone, where the partial pressure of the oxygen is higher than in the deposition zone,
c) repeating the steps a) and b) until the layer of the first material has reached a desired thickness,
d) moving the substrates through a deposition zone for the second material, having a magnetron sputter source with a precursor of the second material, collecting a thin layer of the second material,
e) moving the substrates through an oxidation zone, where the partial pressure of the oxygen is higher than in the deposition zone,
f) repeating the steps d) and e) until the layer of the second material has reached a desired thickness,
g) repeating the steps a) and f) until the number of layers of the first and the second material has reached a desired number.

The stepwise deposition of one thin layer in combination with the separate reaction zone effects a complete reaction of the sputtered atoms, e.g. Si with reaction gas. The method can be carried-out with different processes, e.g. silicon, tantalum, or titanium—with oxygen as reaction gas, if useful nitrogen. As most applications require oxygen this is described below.

Preferably the thin layers are less than five monolayers.

The inventive further refers to a thin film acoustic reflector stack with alternating layers of a first and a second material having different acoustic characteristic impedances, wherein the layers are deposited alternately by a reactive pulsed dc magnetron sputtering process.

An advantage arrangement for the fabrication of a thin film acoustic reflector stack with alternating layers of a first and a second material having different acoustic characteristic impedances, wherein the layers are deposited alternately by a reactive pulsed dc magnetron sputtering process, comprises:
a) a reaction chamber having means for evacuating and for controlled gas supply,
b) in the reaction chamber a rotating support device, on the periphery of which mounts for substrates are arranged,
c) at least two targets and at least one microwave source being arranged on the periphery of the reaction chamber,
d) magnets being mounted behind the targets, seen from the interior of the reaction chamber, forming a magnetic cage in order to keep and concentrate discharge electrons near to the target surface.

The support device may be formed as drum or as table as it may be useful in the special application.

Although the inventive method requires stepwise deposition of thin layers this arrangement allows the fabrication of large quantities at low costs and high precision. One practically used embodiment can process more than 20 wafers in one batch.

### BRIEF DESCRIPTION OF THE DRAWINGS

These and other aspects of the invention will be apparent from and elucidated with reference to the embodiments described hereinafter.

FIG. 1 is a schematic presentation of a sputter arrangement,

FIG. 2 is a perspective view of a sputter source,

FIG. 3 is a schematic presentation of a reaction chamber,

FIG. 4 shows a section of the reaction chamber according to FIG. 3 in greater detail.

### DESCRIPTION OF PREFERRED EMBODIMENTS

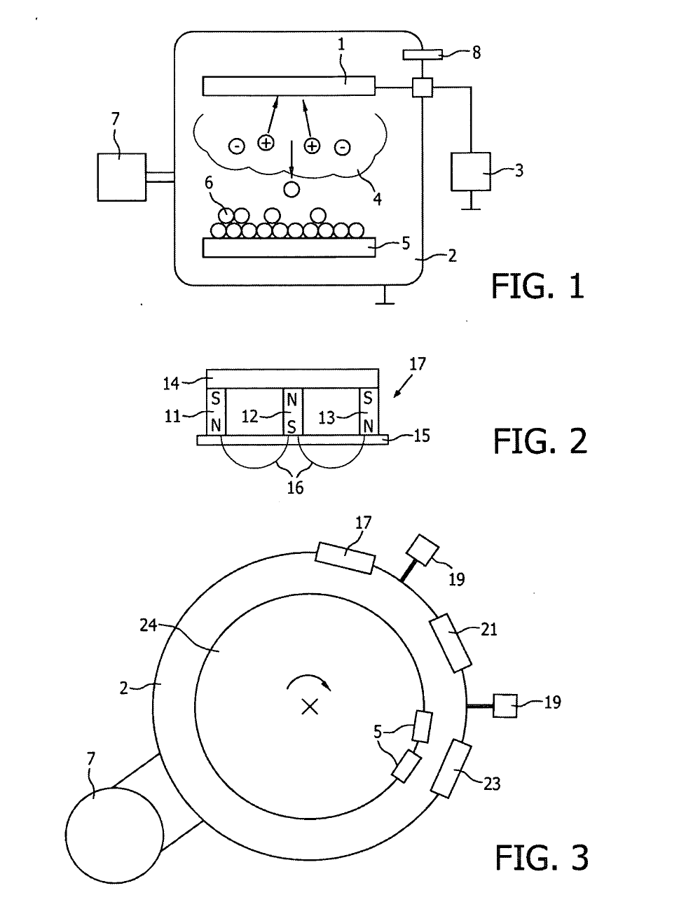

Material to be deposited or some precursor of it is brought as a solid target 1 into a reaction chamber 2, thereby facing the substrate to be coated (FIG. 1). The reactive chamber is evacuated by a vacuum pump 7. An inlet valve 8 allows supplying required gases. The target 1 is energised by a power supply 3 so that an electric discharge forming a plasma 4 in the inert gas (mostly used is Ar) is sustained near the target 1. The target 1 is then subjected to the bombardment of energetic inert gas ions, which dislodge surface atoms via a collision cascade when impinging against the target 1. These target atoms are ejected with a wide angular distribution as indicated in the figure and partly reach the substrate 5, where they are incorporated into the growing layer 6.

In order to increase sputter intensity and process productivity, the magnetron principle shown in FIG. 2 and known per se from Ohring M.: “The Materials Science of Thin Films”, Academic Press, UK, 1992, p. 123 can be applied. Here an arrangement of permanent magnets 11, 12, 13 with a pole piece 14 placed on the back of the target 15 is used to form a “magnetic cage” 16 to keep and concentrate the discharge electrons near to the target surface. This forms the so-called racetrack where the plasma and the sputtering is most intensive.

One of the fastest ways of sputtering is the DC-mode with the target acting as the cathode and the rest of the system being the anode of the discharge. This mode only works with electrically conducting targets. So in order to form dielectric materials (SiO2, Si3N4, TiO2, Ta2O5, . . . ) the targets are made from the corresponding metals, and the other chemical constituent, say oxygen, is brought into the system as a gaseous admixture to the inert gas.

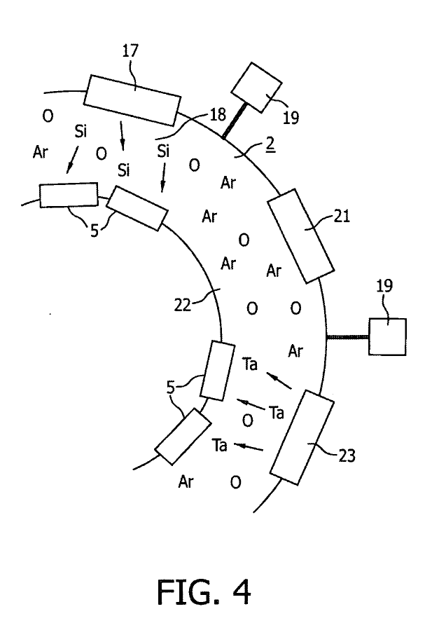

In order to reach a high degree of oxidation of the metal layer, a high partial pressure of oxygen seems desirable. Unfortunately the oxygen not only reacts with the layer material, but also reaches the target forming non conducting layers on the target surface. This results in unstable operation conditions for the sputter process. This problem is solved by using an extra zone for oxidation process, which is schematically depicted in FIGS. 3 and 4.

After pump down of the vacuum system (base pressure of the system is in the lower 10−6 mTorr range) a plasma cleaning step with an Argon plasma (6.5 mTorr Ar) driven by the microwaves (3×4 kW power) is applied to further clean the atmosphere and surfaces in the chamber 31 and to reach the necessary sputter background pressure. The tracer for the cleaning process is the oxygen released from the surfaces to the chamber atmosphere during the microwave plasma action. The oxygen partial pressure is continuously monitored. Preferably cleaning can be done till the oxygen partial pressure falls below 0.05 mTorr.

The substrates are moved through the deposition zone 18 of a magnetron sputter source 17 collecting a thin layer of metal or silicon, e. g. the thickness of which is about one monolayer or less than five monolayers. In the plasma of the sputter source 17 the oxygen fed into the system via a gas controller 19 starts to react with the metal deposited on the substrate 20. But as this is not sufficient to receive a homogeneous layer, extra microwave units 21 are installed, which supply the system with additional reaction zones 22, where the adlayer, i.e. the additional layer in each deposition step, is further oxidized. The build-up of a single layer of an interference filter can take several hundred such passes with the number of passes defining the layer thickness very accurately. As indicated in FIGS. 3 and 4 the system is equipped with different targets 17, 23 for the different materials needed for the interference stack.

Both SiO2 and Ta2O5 are deposited with single target processes, i.e. only one target is active at a time. The parameter settings are dependent on the material. Typical values are for SiO2: Ar pressure 6.3 mTorr, O2 pressure 0.3 mTorr, Microwave power 3×5 kW, Target power 10 kW. Typical values are for Ta2O5: Ar pressure 6.0 mTorr, O2 pressure 0.5 mTorr, Microwave power 3×5 kW, Target power 8.5 kW. Layer thickness calibration is done by test depositions and optical measurement of the layer thickness of e. g. 500 nm found on the test samples. Deposition rates depend on substrate geometry and target powers. According to experiments they are in the region of 25 nm/min.

1. A method for the fabrication of a thin film acoustic reflector stack with alternating layers of a first and a second material having different acoustic characteristic impedances, wherein at least one of the layers is deposited by a reactive dc magnetron sputtering process.

2. A method according to claim 1, wherein the sputtering process is pulsed.

3. A method according to claim 1, wherein both layers are deposited alternately by the sputtering process.

4. A method according to claim 1, wherein a plurality of substrates are placed in a vacuum reaction chamber containing an inert gas and a reaction gas, comprising the steps of:
h) moving the substrates through a deposition zone for the first material, having a magnetron sputter source with a precursor of the first material, collecting a thin layer of the first material,
i) moving the substrates through a reaction zone, where the partial pressure of the oxygen is higher than in the deposition zone,
j) repeating the steps a) and b) until the layer of the first material has reached a desired thickness,
k) moving the substrates through a deposition zone for the second material, having a magnetron sputter source with a precursor of the second material, collecting a thin layer of the second material,
l) moving the substrates through an oxidation zone, where the partial pressure of the oxygen is higher than in the deposition zone,
m) repeating the steps d) and e) until the layer of the second material has reached a desired thickness,
n) repeating the steps a) and f) until the number of layers of the first and the second material has reached a desired number,

5. A method according to claim 4, wherein one of the precursors is silicon.

6. A method according to claim 4, wherein one of the precursors is tantalum.

7. A method according to claim 4, wherein one of the precursors is titanium

8. A method according to claim 4, wherein the reaction gas is oxygen.

9. A method according to claim 4, wherein the reaction gas is nitrogen.

10. A method according to claim 4, wherein the thin layers are less than five monolayers.

11. A thin film acoustic reflector stack with alternating layers of a first and a second material having different acoustic characteristic impedances, wherein the layers are deposited alternately by a reactive pulsed dc magnetron sputtering process.

12. An Arrangement for the fabrication of a thin film acoustic reflector stack with alternating layers of a first and a second material having different acoustic characteristic impedances, wherein the layers are deposited alternately by a reactive pulsed dc magnetron sputtering process, comprising:
e) a reaction chamber having means for evacuating and for controlled gas supply,
f) in the reaction chamber a rotating support device, on the periphery of which mounts for substrates are arranged,
g) at least two targets and at least one microwave source being arranged on the periphery of the reaction chamber,
h) magnets being mounted behind the targets, seen from the interior of the reaction chamber, forming a magnetic cage in order to keep and concentrate discharge electrons near to the target surface.
